(19) United States
(12) Patent Application Publication
(10) Pub. No.: US 2016/0336175 A1
(43) Pub. Date: Nov. 17, 2016

(54) METHOD AND APPARATUS FOR FORMING OXIDE THIN FILM

(71) Applicant: YAMAGATA UNIVERSITY, Yamagata (JP)

(72) Inventors: Fumihiko HIROSE, Yamagata (JP); Kensaku KANOMATA, Yamagata (JP)

(21) Appl. No.: 15/106,661

(22) PCT Filed: Dec. 11, 2014
(86) PCT No.: PCT/JP2014/082840

§ 371 Date: Jun. 20, 2016

(30) Foreign Application Priority Data
Dec. 18, 2013 (JP) 2013-261850

(51) Int. Cl. H01L 21/02; H01J 37/32; C23C 16/505; C23C 16/18; C23C 16/52

(52) U.S. Cl. CPC H01L 21/02274; H01L 21/02205; H01L 21/02181; H01L 21/02189; C23C 16/18; C23C 16/52; C23C 16/505; H01J 37/3211; H01J 2237/3321

(57) ABSTRACT

Disclosed is a method for forming an oxide thin film on a solid substrate, the method including the steps of placing a solid substrate s a in a reaction container 1, maintaining the solid substrate at a temperature of higher than 0° C. and 150° C. or lower, and filling the reaction container with an organometallic gas containing tetrakis(ethylmethylamino)hafnium or tetrakis(ethylmethylamino)zirconium; discharging the organometallic gas from the reaction container or filling the reaction container with an inert gas; treating a gas containing oxygen and water vapor with plasma, to thereby generate a plasma gas containing excited oxygen and water vapor, and feeding the plasma gas into the reaction container; and discharging the plasma gas from the reaction container or filling the reaction container with an inert gas; and repeating the series of steps.

### TECHNICAL FIELD

The present invention relates to a method and an apparatus for forming, on a solid substrate, a hafnium oxide thin film or a zirconium oxide thin film at low temperature.

### BACKGROUND ART

Hitherto, transistor elements of field-effect transistors—main elements of semiconductor integrated circuits—have been downscaled to very small dimensions, for increasing the integration degree of such circuits. Particularly when the channel area of such a field-effect transistor is reduced, driving current problematically lowers. Thus, in order to mitigate the driving current problem, efforts are made for reducing the thickness of a gate insulating film.

In recent years, gate insulating films are made of a high-dielectric-constant oxide such as HfO₂. When such an insulating film has a thickness of less than 10 nm, the interface between the insulating film and the semiconductor on which the insulating film is stacked may affect the performance of the transistor having the semiconductor. Generally, Si, Ge, and GaAs are used as semiconductor materials. In recent years, among these materials, Ge tends to be selected for attaining high carrier mobility and high current driving performance (see Patent Document 1). However, as has been known, when the above oxide is stacked on a semiconductor layer, semiconductor-oxide solid phase reaction occurs during the stacking process. In this case, an oxygen-deficient Ge compound such as GeO₂ or GeO is formed, which Ge compound may considerably impair the performance of the field-effect transistor. Some studies have indicated that, in the case where HfO₂ is stacked on a semiconductor layer made of Si, solid phase reaction occurs to form HfSiO, which impairs the current driving performance of the field-effect transistor. In order to suppress the solid phase reaction between such an oxide and a semiconductor, stacking of the oxide thin film on the semiconductor must be carried out at a lower temperature.

Meanwhile, thin film made of hafnium oxide is resistant to corrosion by acid or alkali. Hafnium oxide is chemically stable for its very high melting point of 2,774° C. Therefore, hafnium oxide is envisaged to be employed as a protective film such as an anti-corrosive coating film. A particularly promising use of the anti-corrosion coating is coating materials applied onto polymer molded products such as plastic articles. When a polymer molded product is coated with a coating film, the relevant coating step is preferably performed at 50° C. or lower, desirably at room temperature, where the plastic is not deformed.

Similar to hafnium oxide thin film, zirconium oxide thin film has the same physical properties. That is, zirconium oxide thin film is resistant to corrosion by acid or alkali and chemically stable for its very high melting point of 2,715° C. Therefore, zirconium oxide is envisaged to be employed as a protective film such as an anti-corrosive coating film.

Such hafnium oxide thin film and zirconium oxide thin film may be stacked through, for example, an atomic layer deposition (ALD) technique. In ALD, a solid substrate (a solid substrate on which oxide film is to be deposited) is placed in a reaction container, and the substrate is heated at about 250° C. to 400° C. Under this heating condition, a gas of an organometallic compound such as tetrakis(ethylmethylamino)hafnium or tetrakis(ethylmethylamino)zirconium is charged into the reaction container. Then, the gas is discharged from the reaction container, and an oxidizing gas such as ozone or water vapor is fed into the reaction container. The oxidizing gas is then discharged. Through repetition of these steps, an oxide thin film is stacked on the substrate. When the organometallic gas is fed into the reaction container, the surface of the substrate is exposed to the gas, whereby organometallic gas molecules are adsorbed on the surface of the substrate to saturation. When the substrate is exposed to the oxidizing gas, the organometallic gas molecules deposited on the surface of the substrate are oxidized, whereby an oxide thin film having a thickness equivalent to a unimolecular layer is formed on the surface of the substrate. The procedure including these steps is called an ALD cycle. Through repetition of the ALD cycle, a plurality of oxide film layers are successively formed, with the number of layers being equivalent to the number of repetitions of the ALD cycle. The substrate temperature is controlled to 250° C. to 400° C. for the following reasons. Specifically, when the substrate temperature is higher than the upper limit, decomposition of the organometallic gas is promoted during the adsorption process. In this case, the thickness of the formed film exceeds the unimolecular-equivalent thickness in a single gas feeding step, failing to attain an adsorption saturation state. Eventually, the formed film is not an oxide film, but a metallic film. Also, when the substrate temperature is lower than 250° C., occurrence of organometallic gas molecule adsorption decreases, thereby failing to form oxide film. Both cases are problematic.

As described above, when hafnium oxide is formed on a semiconductor layer, solid phase reaction occurs at the interface therebetween, to thereby problematically form an undesired layer. In addition, when hafnium oxide film is formed on a polymer article or the like, the film formation step must be carried out at a lowest possible temperature close to room temperature. Even though the aforementioned atomic layer deposition technique is employed, the process requires a temperature of 250° C. or higher, through which the interface layer is undesirably stacked a plurality of times, or the plastic article is deformed. Thus, there is demand for such a film formation process which can be performed at a lower temperature.

### PRIOR ART DOCUMENTS

### Non-Patent Documents

### [Non-Patent Document 1]

Electrochemical and Solid-State Letters, Vol. 9, 2006, G285 to G288

### SUMMARY OF THE INVENTION

### Problems to be Solved by the Invention

The present invention has been conceived in consideration of the aforementioned circumstances. Thus, an object of the present invention is to form a hafnium oxide thin film, which serves as a gate oxide film of a field-effect transistor, at a low temperature. Another object is to form a hafnium oxide thin film or a zirconium oxide thin film on a plastic substrate at a low temperature.

### Means for Solving the Problems

The inventors have found that an oxide thin film can be formed through a series of the following steps: placing a target solid substrate in a reaction container, maintaining the solid substrate at a temperature of higher than 0° C. and 150° C. or lower, and filling the reaction container with an organometallic gas containing tetrakis(ethylmethylamino)hafnium or tetrakis(ethylmethylamino)zirconium; discharging the organometallic gas from the reaction container or filling the reaction container with an inert gas; treating a gas containing oxygen and water vapor with plasma, to thereby generate a plasma gas containing excited oxygen and water vapor, and feeding the plasma gas into the reaction container; and discharging the plasma gas from the reaction container or filling the reaction container with an inert gas; and repeating the series of steps.

Accordingly, in one aspect of the present invention to attain the aforementioned objects, there is provided a method for forming an oxide thin film on a solid substrate, characterized in that the method comprises a series of steps of:

placing the solid substrate in a reaction container, maintaining the solid substrate at a temperature of higher than 0° C. and 150° C. or lower, and filling the reaction container with an organometallic gas containing tetrakis(ethylmethylamino)hafnium or tetrakis(ethylmethylamino)zirconium;

discharging the organometallic gas from the reaction container or filling the reaction container with an inert gas;

treating a gas containing oxygen and water vapor with plasma, to thereby generate a plasma gas containing excited oxygen and water vapor, and feeding the plasma gas into the reaction container; and

discharging the plasma gas from the reaction container or filling the reaction container with an inert gas; and

repeating the series of steps.

Preferably, the plasma gas is formed by feeding water vapor-added oxygen into an insulated tube, and applying high-frequency magnetic field to the insulated tube at an electric power of 3.8 W/cm² or greater per cross-section of the inside of the insulated tube, to thereby generate plasma inside the insulated tube.

Preferably, the aforementioned water vapor-added oxygen is formed by bringing oxygen into contact with water at a temperature higher than 0° C. and not exceeding 80° C.

Preferably, the oxide thin film formation method further includes, before the first contact of the solid substrate with the organometallic gas, a step of treating the solid substrate with a plasma gas generated from a gas containing at least water vapor.

Preferably, the dose of the organometallic gas which is tetrakis(ethylmethylamino)hafnium or tetrakis(ethylmethylamino)zirconium is adjusted to 1.0×10⁻² Torr·s or higher or 1.0×10⁵ Langmuir units or higher, at the surface of the substrate to be treated.

Preferably, the dose of the plasma gas is adjusted to 0.15 Torr·s or higher or 1.5×10⁵ Langmuir units or higher, at the surface of the substrate to be treated.

In another aspect of the present invention, there is provided an apparatus for forming an oxide thin film, the apparatus comprising:

a reaction container having a mechanism for sustaining a substrate;

a temperature-controlling mechanism which can maintain the substrate at a temperature of higher than 0° C. and 150° C. or lower;

a source-feeding apparatus for feeding tetrakis(ethylmethylamino)hafnium or tetrakis(ethylmethylamino)zirconium;

a plasma gas generating apparatus adapted to feed water vapor-containing oxygen into a glass tube, and to apply high-frequency magnetic field to the glass tube, to thereby generate plasma inside the glass tube, thereby providing a plasma gas;

a first determination mechanism for determining the dose of tetrakis(ethylmethylamino)hafnium during feeding thereof in the reaction container; and

a second determination mechanism for determining the dose of the plasma gas in the reaction container.

### Effects of the Invention

According to the present invention, a hafnium oxide film used as a gate oxide film of a field-effect transistor in an integrated circuit, or a hafnium oxide film or a zirconium oxide film used as a protective film for a plastic article or the like can be formed at a lower temperature.

### BRIEF DESCRIPTION OF THE DRAWINGS

FIG. 1 A schematic view of a thin film formation apparatus according to an embodiment of the present invention.

FIG. 2 A schematic view for illustrating a plasma gas generating apparatus according to an embodiment of the present invention.

FIG. 3 A graph showing changes in Hf photoelectron intensity from the surface of the target substrate with variation of the number of ALD cycles, in one example.

FIG. 4 A graph showing the relationship between the number of ALD cycles and the thickness of hafnium oxide film, in one example.

FIG. 5 An IR chart showing surface deposits on the surface of hafnium oxide film after adsorption of tetrakis(ethylmethylamino)hafnium on the surface, observed in one example.

FIG. 6 An IR chart showing surface deposits on the surface of hafnium oxide film after adsorption of tetrakis(ethylmethylamino)hafnium on the surface and feeding of a plasma gas into the reaction container, observed in one example.

FIG. 7 A graph showing the relationship between the number of ALD cycles and the thickness of hafnium oxide film, in one comparative example (the plasma gas generated under no humidification).

### MODES FOR CARRYING OUT THE INVENTION

The present invention will next be described in detail.

In the formation of a hafnium oxide film through atomic layer deposition, tetrakis(ethylmethylamino)hafnium (Hf[NCH₃C₂H₅]₄) is used as a source gas. For forming and stacking a zirconium oxide thin film, tetrakis(ethylmethylamino)zirconium (Zr[NCH₃C₂H₅]₄), having substantially the same molecular structure and physical properties as those of the hafnium material, is used as a source gas. Hereinafter, the present invention will be described, taking hafnium oxide thin film as an example. However, note that formation of zirconium oxide thin film may be carried out through the same procedure, except for the source.

Firstly, a solid to be treated (hereinafter may be referred to as a “solid object”) is placed in a vacuum container (reaction container). The solid object may be an object made of inorganic material, metal, plastic resin, etc. At the start of film formation, hydroxyl groups are provided on the surface of the solid object, in order to facilitate deposition of a source gas. Specifically, a mixture of water vapor and oxygen is treated with plasma, to thereby form a gas containing excited water vapor and oxygen species (hereinafter referred to as a “plasma gas”). The plasma gas is fed into the vacuum container. The plasma gas generated via excitation of the water vapor-oxygen mixture with plasma contains active oxygen, atomic oxygen, active water, OH, atomic hydrogen, and the like. In the case where the substrate to be treated is a metallic object, hydroxyl groups (OH groups) are formed on the surface of the substrate via the following reaction mechanism, wherein M represents a metal atom:

M-M+O→M-O-M

M-O-M+H+OH→2M-OH.

When the substrate to be treated is an organic polymer object, alkyl groups thereof are partially oxidized with oxygen via the following reaction:

—CH₃+O→—CH₂OH,

to thereby introduce hydroxyl groups into the surface of the substrate.

Notably, the above plasma treatment is not necessarily performed before the start of film formation, and may be carried out in consideration of the surface conditions of the solid object. Also, the plasma gas does not necessarily contain oxygen at the start of film formation, and the surface of the object may be treated with a plasma gas obtained from a gas containing at least water vapor.

After formation of hydroxyl groups on the surface of the treatment object (e.g., a plastic surface or a metallic surface), the vacuum container is filled with tetrakis(ethylmethylamino)hafnium gas, instead of a plasma gas obtained from water vapor and oxygen. The hafnium source gas reacts with hydroxyl groups present on the solid surface even at room temperature, whereby the molecules of the Hf source gas are adsorbed on the surface of the substrate. Subsequently, the substrate is exposed to the Hf source gas until the hydroxyl groups present on the surface are completely covered with the source gas, to thereby attain saturation of source gas adsorption. In this case, the dose of the source gas is 10,000 L or more, wherein unit L (Langmuir) represents a dose of the source gas at 1×10⁻⁶ Torr for 1 second. The present inventors have elucidated the adsorption saturation condition by investigating the dose to saturation and the surface conditions through infrared spectroscopy.

When the plasma gas is fed to the adsorption-saturated surface, alkylamino groups of the source gas molecules are completely oxidized, whereby hydroxyl groups are formed on the surface. At this stage, a hafnium oxide film having a thickness equivalent to a unimolecular layer is formed on the surface of the substrate. As determined through extensive studies by the inventors, the plasma gas employed is preferably a gas obtained by exciting a mixture of oxygen and water vapor by means of an induction coil. Rather than use of a plasma gas formed of water vapor or oxygen as a solo ingredient, a mixture of water vapor and oxygen must be used. After contact with plasma, oxygen is present as active oxygen, monoatomic oxygen, and ozone. These oxygen species effectively oxidize hydrocarbon residues of adsorbed source gas molecules. After contact with plasma, water vapor generates OH radicals, which adsorb onto the surface of the substrate, to thereby provide a hydroxylated (OH) surface. As a result, in the subsequent source gas adsorption step, adsorption density can be enhanced. When a plasma gas of water vapor is employed, oxidation is incomplete, thereby failing to form oxide film, whereas when a plasma gas of oxygen is employed, occurrence of source gas adsorption decreases, problematically resulting in low and variable film formation rate and difficulty in controlling the film thickness.

The method of generating the plasma gas will be described. Firstly, oxygen gas is passed through pure water maintained at a specific temperature, to thereby humidify the oxygen gas. The thus-humidified oxygen gas is fed into an insulated tube made of a material such as glass (hereinafter referred to simply as a “glass tube”). A 13.56-MHz high-frequency magnetic field generated by means of an induction coil is applied to the glass tube, whereby plasma is generated in the glass tube. As determined through extensive studies by the inventors, the electric power of the high-frequency magnetic field may be 20 to 30 W, when a glass tube having an inner diameter of 10 to 20 mm is used. Even when the electric power is further elevated, no effect commensurate with the elevation is attained. When the electric power is excessively low, plasma fails to be generated, which is problematic.

The pressure in the vacuum container upon feed of the plasma gas into the substrate to be treated is about 2 Pa. When the dose on the surface of the substrate to be treated is 1.5×10⁵ L or more, the aforementioned effects attributed to oxidation and formation of OH groups can be attained. In order to control the partial pressure of water vapor plasma so as to attain the pressure, pure oxygen gas is passed through water at room temperature; for example, within a temperature range of 23° C. to 60° C.

In the present invention, the aforementioned steps of filling the reaction container accommodating the substrate to be treated with tetrakis(ethylmethylamino)hafnium, and feeding a plasma gas of oxygen and water vapor into the container are performed as a unit cycle. Through repeatedly carrying out the unit cycle, hafnium oxide film having a thickness in proportion to the number of repetitions can be formed.

According to the present invention, a solid substrate is placed in a reaction container, and the solid substrate is maintained at a temperature of higher than 0° C. and 150° C. or lower, preferably 100° C. or lower. Subsequently, the reaction container is filled with a gas of an organometallic compound such as tetrakis(ethylmethylamino)hafnium (first step). Then, a plasma gas is fed to the container (second step). A series of two steps are repeated, to thereby form an oxide thin film in the solid substrate. By filling the reaction container with an organometallic gas, the gas can be adsorbed, to saturation, onto the hydroxyl groups provided on the surface of the substrate even at room temperature (23° C.) Subsequently, a plasma gas is fed to the container, to thereby oxidize and decompose the organometallic gas, leading to formation of hydroxyl groups on the surface of the substrate. The temperature of the solid substrate is limited to 150° C. or lower. Generally, in the field of integrated circuits to which this technique is applied, a metal (Al, Au, etc.) film and an indium film is formed on a semiconductor substrate. The above temperature limitation is effective for suppressing oxidation, peeling, and melting of such metals. Further, the solid substrate is limited to 100° C. or lower, for possibly and effectively preventing generation of GeO serving as an interface layer between Ge and oxide in the case where the semiconductor substrate is made of Ge. The substrate temperature is controlled to exceed 0° C., for preventing freezing of water (a reaction product) on the surface of the substrate.

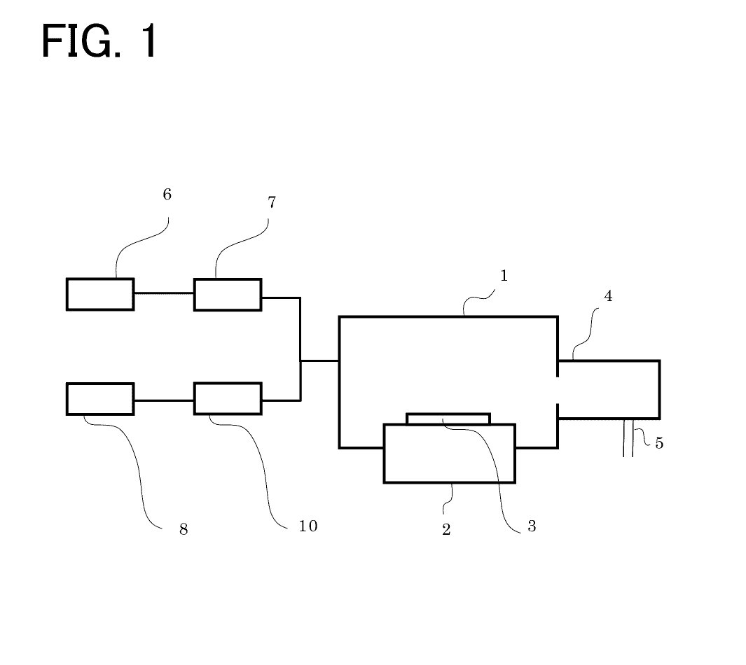

FIG. 1 is a schematic view illustrating an oxide film formation apparatus according to an embodiment of the present invention.

In an apparatus for forming an oxide thin film falling within the scope of the present invention, a substrate to be treated 3 is placed on a temperature-controlling plate 2 disposed in a reaction container 1. The reaction container 1 is connected to a discharge pump 4, whereby the gas present in the reaction container 1 can be discharged through a gas discharge conduit 5. To the reaction container 1, a source tank 6 containing tetrakis(ethylmethylamino)hafnium is connected via a flow controller 7. Also, an oxygen tank 8 is connected to the reaction container 1 via a plasma gas generating apparatus 10. For forming a zirconium oxide thin film, the source tank 6 is filled with tetrakis(ethylmethylamino)zirconium. An embodiment of forming a hafnium oxide thin film will next be described. Since tetrakis(ethylmethylamino)hafnium serving as a source gas has the same molecular structure and functional group configuration and substantially the same physical properties and reactivity as those of tetrakis(ethylmethylamino)zirconium, the procedure may also be applied to formation of a zirconium oxide film, if the Hf source is changed to the Zr source.

In the case where an object such as an In film is formed on the substrate to be treated 3, the temperature-controlling plate 2 is maintained at 150° C. or lower, to thereby prevent melting of In. When the substrate to be treated is made of Ge, the substrate is preferably maintained at 100° C. or lower, whereby formation of GeO at the interface between the oxide thin film and the Ge substrate can be effectively prevented. Formation of GeO considerably impairs the insulation performance of the formed oxide film. By controlling the substrate temperature to exceed 0° C., freezing of water vapor (a reaction product) on the surface of the substrate can be prevented. In any case, the temperature-controlling plate 2 is generally maintained at room temperature (23° C.). The same effect can be attained, when the reaction container itself is maintained at room temperature (23° C.)

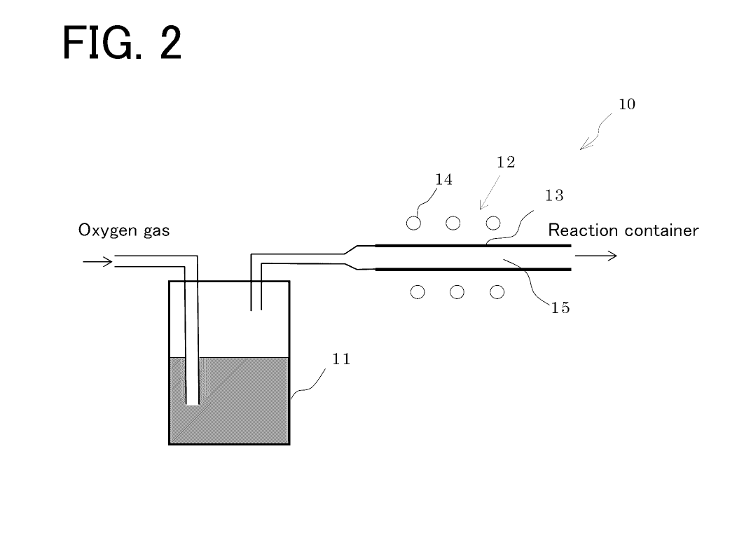

FIG. 2 is a schematic view for illustrating the plasma gas generating apparatus 10 according to an embodiment of the present invention. The plasma gas generating apparatus 10 has a water bubbler 11 and a plasma generator 12. The plasma generator 12 has a glass tube 13 and an induction coil 14 disposed to surround the glass tube 13. The induction coil generates plasma in an inner portion 15 of the glass tube. The water bubbler 11 retains water, to which oxygen gas is supplied. Through passing oxygen through the water bubbler 11, oxygen gas is humidified, to thereby provide a mixture of oxygen and water vapor.

In the plasma gas generating apparatus 10, the humidified oxygen gas produced through the water bubbler 11 is fed into a glass tube 13 and caused to pass through the plasma-generated portion 15 in which plasma has been generated by high-frequency magnetic field applied by means of the induction coil 14. As a result, a plasma gas formed of activated oxygen-water vapor is produced, and then supplied to the reaction container 1. In the present embodiment, the induction coil 14 employs a high-frequency power of 20 W and a frequency of 13.56 MHz.

### Example 1

HfO₂ film was formed by means of the aforementioned apparatus.

In Example 1, tetrakis(ethylmethylamino)hafnium was used as a source gas, and an HfO₂ film was formed on the surface of the substrate to be treated 3. The substrate to be treated 3 was maintained at 23° C. The substrate to be treated 3 employed was a silicon single-crystal plate with a plane orientation (100). Film formation was carried out through the following procedure. Firstly, the reaction container 1 was treated with a plasma gas. The plasma gas was fed for 5 minutes. The plasma gas was produced by means of the apparatus shown in FIG. 2. Oxygen gas was caused to flow through the water bubbler 11 at a flow rate of 7 sccm. The temperature of water in the water bubbler 11 was controlled to 60° C., and a humidified oxygen gas was produced. Subsequently, plasma was generated in the glass tube 13 by means of the induction coil 14. A mixture of water vapor and oxygen was treated with the generated plasma, to thereby activate the mixture. The induction coil 14 employed a high-frequency power of 20 W. As a result, the surface of the substrate to be treated 3 was oxidized, and greasy stain was removed. Hydroxyl groups were provided in the surface of the substrate. Thus, the efficiency of adsorption of tetrakis(ethylmethylamino)hafnium introduced thereafter can be enhanced.

The plasm gas was fed to the reaction container 1, and then tetrakis(ethylmethylamino)hafnium was fed to the container for one minute. At this timing, the partial pressure of tetrakis(ethylmethylamino)hafnium in the reaction container 1 was 1.8×10⁻¹ Pa. The dose of tetrakis(ethylmethylamino)hafnium at the surface of the substrate to be treated 3 was adjusted to 81,202 L. Thereafter, the reaction container 1 was evacuated by means of the discharge pump 4. Subsequently, the plasma gas was fed to the reaction container 1 for 2 minutes at a flow rate of 10 sccm, to thereby oxidize tetrakis(ethylmethylamino)hafnium adsorbed on the substrate to be treated 3, to thereby provide hydroxyl groups on the surface of the substrate. Through provision of hydroxyl groups, occurrence of adsorption of tetrakis(ethylmethylamino)hafnium molecules in the subsequent step can be enhanced.

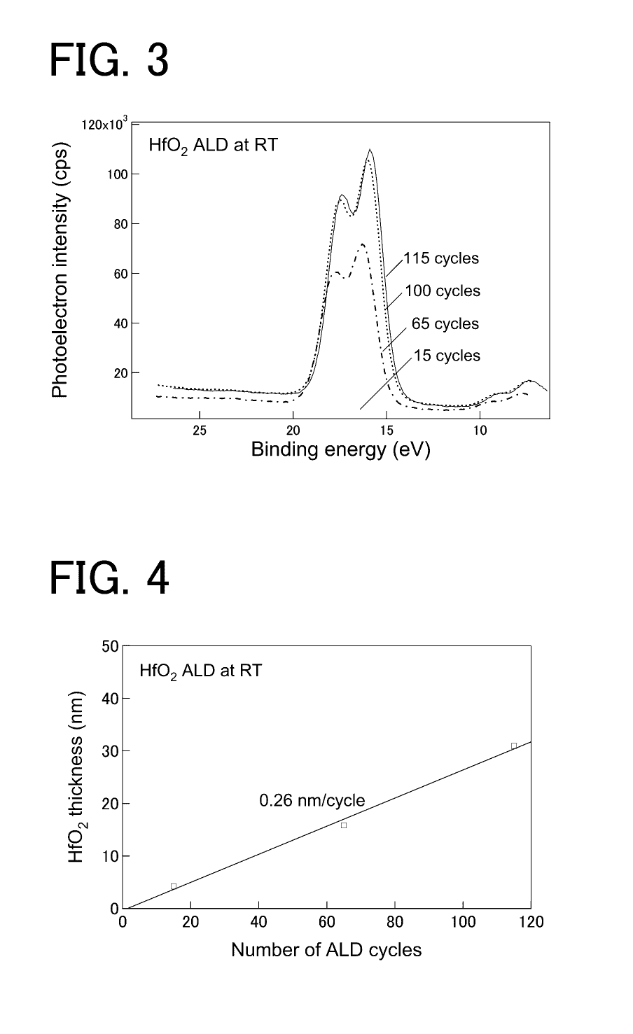

In the present specification, the aforementioned series of the steps is called an “ALD cycle.” When the number of repetitions of the ALD cycle increased, the feature of formation of hafnium on the substrate to be treated 3 was monitored through X-ray photoelectron spectrometry. FIG. 3 shows the results. As the number of repetitions of ALD cycles increased, the photoelectron intensity attributed to Hf_{4f} increased. Since the peak was found to be at 16.2 eV, as a bonding energy, the film formed by the stacking process was identified to be an HfO₂ film. Assuming the HfO₂ film was formed on the surface of the substrate to be treated 3 was found to have a uniform thickness d, the spectral intensity I in photoelectron spectroscopy is represented by the following formula:

$$I = A \{ 1 - {e}^{\frac{d}{λ}} \} \qquad [ F1 ]$$

In the above formula, A represents a proportionality coefficient, and λ represents a depth required for emitting photoelectrons from hafnium oxide. Based on the above formula, the thickness of the formed oxide film was re-calculated from the photoelectron intensity attributed to Hf_{4f}. The results are shown in FIG. 4. As the number of repetitions of ALD cycles increases, the thickness increases in proportion to the number of repetitions. As is clear from FIG. 4, an HfO₂ film having a thickness of 0.26 nm was formed in each ALD cycle.

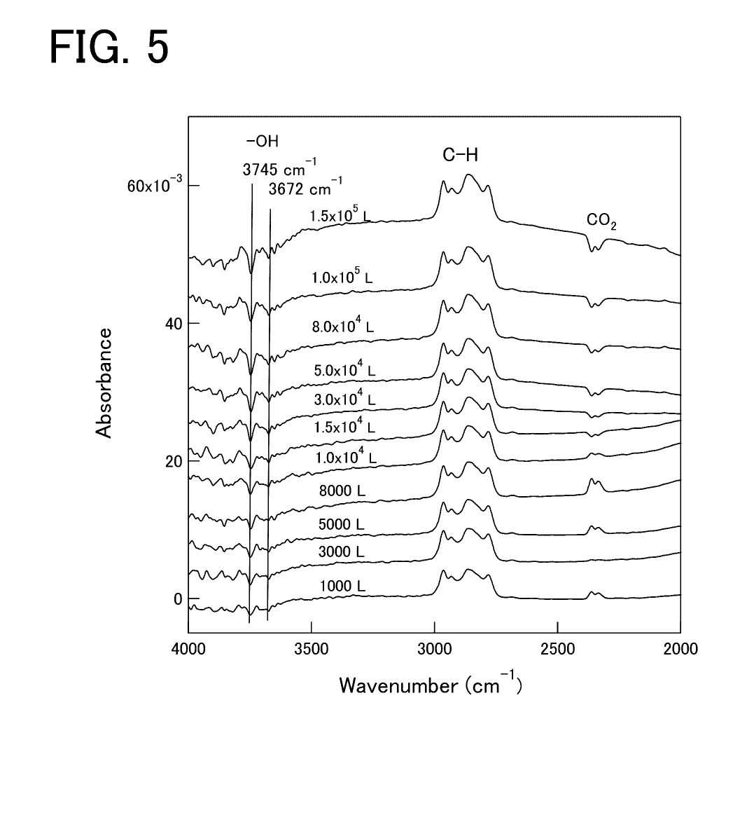

The change in chemical condition of the surface of the substrate to be treated 3 in Example 1, when tetrakis(ethylmethylamino)hafnium was fed, was assessed through infrared spectroscopy. FIG. 5 shows the results. In FIG. 5, the dose of the hafnium compound is represented by Langmuir units (L). When the dose of tetrakis(ethylmethylamino)hafnium was varied from 1,000 L to 1.5×10⁵ L, the IR absorption spectrum was changed. As the dose increased, the absorbance attributed to the hydrocarbon group increased in the wavelength range of 2,750 cm⁻¹ to 3,000 cm⁻¹. This increase in absorbance indicates adsorption of tetrakis(ethylmethylamino)hafnium molecules onto the surface of the substrate, providing an infrared absorption peak attributed to the hydrocarbon group on a molecule thereof. Also, as the dose increased, drops in absorbance were observed at 3,745 cm⁻¹ and 3,672 cm⁻¹. The drops indicate consumption of hydroxyl (OH) groups at the surface of the substrate, and adsorption of the hafnium compound molecules onto the surface by the mediation of OH groups. In FIG. 5, no change was observed in IR spectra when the dose was 1×10⁴ L or more, indicating saturation in adsorption. That is, Example 1 has proven that, when the dose of tetrakis(ethylmethylamino)hafnium is adjusted to 1×10⁴ L or more, adsorption of the molecule can be saturated, ensuring adsorption thereof onto the surface at a constant density in each adsorption process.

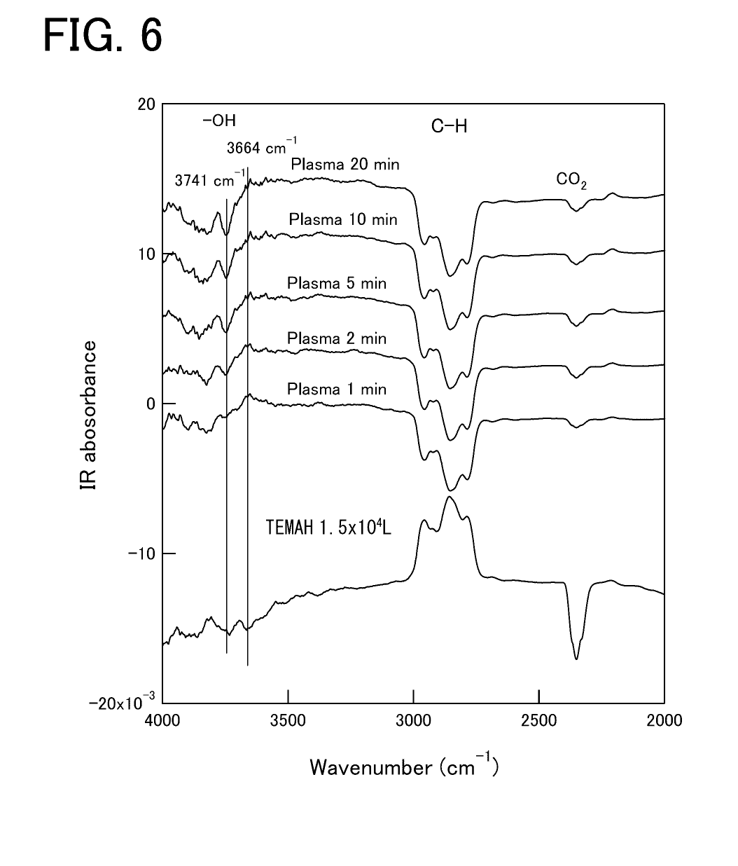

FIG. 6 is an IR chart showing changes in surface conditions of the substrate after adsorption of tetrakis(ethylmethylamino)hafnium to saturation on the surface and then feeding of a plasma gas into the reaction container, observed in Example 1. The curve at the bottom of the IR chart shows an increase in IR absorbance attributed to adsorption of tetrakis(ethylmethylamino)hafnium to saturation. When the plasma gas was fed to the container for 1 minute to 20 minutes, drops in absorbance attributed to the hydrocarbon group of tetrakis(ethylmethylamino)hafnium were observed in the wavelength range from 2,750 cm⁻¹ to 3,000 cm⁻¹. The amount of each drop was almost the same as the increase in absorbance after adsorption of the hafnium compound to saturation. Thus, the hydrocarbon groups introduced through adsorption to saturation were found to be oxidized and decomposed by the plasma gas treatment. In addition, the IR absorbance at 3,664 cm⁻¹ increased through the plasma gas treatment. The increase indicates formation of hydroxyl groups on the surface of the substrate. Thus, the plasma gas was found to be effective for oxidation of the surface of the tetrakis(ethylmethylamino)hafnium-adsorbed layer and formation of hydroxyl groups on the surface. As is clear from FIG. 6, the plasma gas treatment was sufficiently completed within one minute. Therefore, since the pressure of the plasma gas fed was 2.5×10⁻³ Torr, the above effects can be attained when the dose of the plasma gas is 0.15 Torr·s or more. The dose, as reduced to Langmuir units, is 1.5×10⁵ L (1 L=10⁻⁶ Torr·s).

The oxide film formed in Example 1 was analyzed through X-ray photoelectron spectroscopy, to thereby determine the composition thereof. As a result, the atomic ratio of Hf to O was 1:2.06, which is approximate to the theoretical (stoichiometric HfO₂) atomic ratio of 1:2. Also, nitrogen was detected as an impurity. The amount of nitrogen was about 36% with respect to Hf (by atomic concentration). Since nitrogen can be removed through heating or another technique, the presence of nitrogen is not problematic in practice.

### Example 2

The procedure of Example 1 was repeated, except that the temperature of the water bubbler 11 was set to 23° C. (room temperature). As a result, virtually the same characteristic of adsorption of tetrakis(ethylmethylamino)hafnium to saturation as conformed in Example 1 was attained. No particular problem was involved in formation of HfO₂ film.

### Comparative Example 1

The procedure of Example 1 was repeated, except that a plasma gas was generated by means of an apparatus shown in FIG. 2, wherein argon instead of oxygen was caused to pass through the water bubbler 11. The thus-humidified argon was excited and fed to the reaction container. Even after performing 100 ALD cycles, no hafnium oxide was detected from the substrate to be treated. Detection was carried out through photoelectron spectroscopy, but no photoelectron peak (Hf_{4f}) attributed to hafnium present at the surface of the substrate was detected. Thus, HfO₂ cannot be formed through the method of Comparative Example 1.

### Comparative Example 2

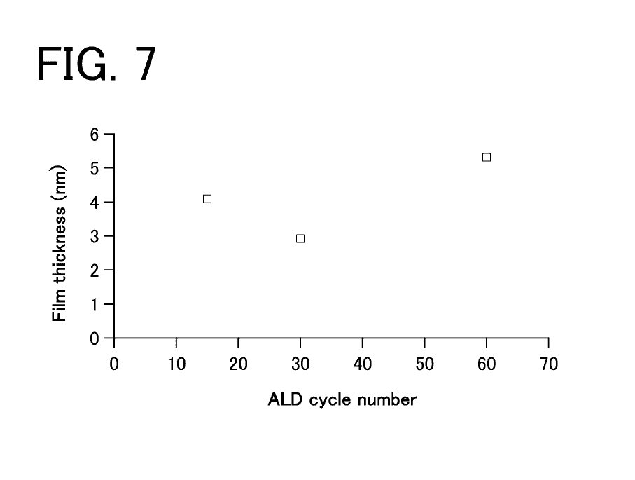

The procedure of Example 1 was repeated, except that a plasma gas was generated by means of an apparatus shown in FIG. 2, wherein oxygen was not caused to pass through the water bubbler 11. The dry oxygen was fed to the glass tube 13 and treated with plasma generated in the tube, so as to from HfO₂ film. As a result, an oxide film was formed on the substrate to be treated 3. However, as shown in FIG. 7, no proportional relationship was obtained between film formation rate and number of ALD cycles. The film formation rate per cycle varied in a range from 0.27 nm/cycle to 0.089 nm/cycle, indicating that this method encounters difficulty in controlling the film thickness.

The oxide film formed in Comparative Example 2 was analyzed through X-ray photoelectron spectroscopy, to thereby determine the composition thereof. As a result, the atomic ratio of Hf to O was found to be 1:3.85, which is deviated from the theoretical (stoichiometric HfO₂) atomic ratio of 1:2. The composition of the formed film considerably differs from HfO₂. The formed oxide film was found to contain a large amount of impurity. Thus, the method of Comparative Example 2 encounters difficulty in forming HfO₂ film.

### Comparative Example 3

The procedure of Example 1 was repeated, except that the temperature of the water bubbler 11 was adjusted to 0° C. In Comparative Example 3, passing gas through the water bubbler was impeded by freezing of water. Separately, when the temperature of the water bubbler 11 was in excess of 80° C., water drops were deposited inside the glass tube 13 and the discharge conduit 5, making discharge from the reaction container 1 difficult. Therefore, it is effective that the temperature of the water bubbler is adjusted to be lower than 80° C. and higher than 23° C. (room temperature).

### Comparative Example 4

The procedure of Example 1 was repeated, except that the high-frequency power input to the induction coil 14 for generating a plasma gas was adjusted to 20 W and 30 W. As a result, no particular change was observed in oxidation characteristics. Separately, when the high-frequency power was tuned from 10 W to 15 W, difficulty was encountered in electric discharge. Comparative Example 4 revealed that the high-frequency power input to the induction coil was suitably 20 W and 30 W. The glass tube employed in Comparative Example 4 had a size of 13 mm. Thus, it is appropriate that the high-frequency power per cross-section of the glass pipe is adjusted to be 3.8 W/cm² or more.

### INDUSTRIAL APPLICABILITY

The present invention is employed for forming a gate insulating film of a field-effect transistor employed in electronic devices such as LSIs, and a protective film for a plastic article such as a polymer article.

### BRIEF DESCRIPTION OF REFERENCE NUMERALS

1 reaction container
2 temperature-controlling plate
3 substrate to be treated
4 discharge pump
5 discharge conduit
6 source tank
7 flow controller
8 oxygen tank
10 plasma gas generating apparatus
11 water bubbler
12 plasma generator
13 glass tube
14 induction coil
15 plasma-generated portion

1. A method for forming an oxide thin film on a solid substrate, characterized in that the method comprises a series of steps of:
placing the solid substrate in a reaction container, maintaining the solid substrate at a temperature of higher than 0° C. and 150° C. or lower, and filling the reaction container with an organometallic gas containing tetrakis(ethylmethylamino)hafnium or tetrakis(ethylmethylamino)zirconium;
discharging the organometallic gas from the reaction container or filling the reaction container with an inert gas;
treating a gas containing oxygen and water vapor with plasma, to thereby generate a plasma gas containing excited oxygen and water vapor, and feeding the plasma gas into the reaction container; and
discharging the plasma gas from the reaction container or filling the reaction container with an inert gas; and
repeating the series of steps.

2. An oxide thin film formation method according to claim 1, wherein the plasma gas is formed by feeding water vapor-added oxygen into an insulated tube, and applying high-frequency magnetic field to the insulated tube at an electric power of 3.8 W/cm² or greater per cross-section of the inside of the insulated tube, to thereby generate plasma inside the insulated tube.

3. An oxide thin film formation method according to claim 2, wherein the water vapor-added oxygen is formed by bringing oxygen into contact with water at a temperature higher than 0° C. and not exceeding 80° C.

4. An oxide thin film formation method according to claim 1, which further includes, before the first contact of the solid substrate with the organometallic gas, a step of treating the solid substrate with a plasma gas generated from a gas containing at least water vapor.

5-7. (canceled)

8. An oxide thin film formation method according to claim 2, which further includes, before the first contact of the solid substrate with the organometallic gas, a step of treating the solid substrate with a plasma gas generated from a gas containing at least water vapor.

9. An oxide thin film formation method according to claim 3, which further includes, before the first contact of the solid substrate with the organometallic gas, a step of treating the solid substrate with a plasma gas generated from a gas containing at least water vapor.

10. An oxide thin film formation method according to claim 1, wherein the dose of the organometallic gas which is tetrakis(ethylmethylamino)hafnium or tetrakis(ethylmethylamino)zirconium is adjusted to 1.0×10⁻² Torr·s or higher or 1.0×10⁵ Langmuir units or higher, at the surface of the substrate to be treated.

11. An oxide thin film formation method according to claim 2, wherein the dose of the organometallic gas which is tetrakis(ethylmethylamino)hafnium or tetrakis(ethylmethylamino)zirconium is adjusted to 1.0×10⁻² Torr·s or higher or 1.0×10⁵ Langmuir units or higher, at the surface of the substrate to be treated.

12. An oxide thin film formation method according to claim 3, wherein the dose of the organometallic gas which is tetrakis(ethylmethylamino)hafnium or tetrakis(ethylmethylamino)zirconium is adjusted to 1.0×10⁻² Torr·s or higher or 1.0×10⁵ Langmuir units or higher, at the surface of the substrate to be treated.

13. An oxide thin film formation method according to claim 4, wherein the dose of the organometallic gas which is tetrakis(ethylmethylamino)hafnium or tetrakis(ethylmethylamino)zirconium is adjusted to 1.0×10⁻² Torr·s or higher or 1.0×10⁵ Langmuir units or higher, at the surface of the substrate to be treated.

14. An oxide thin film formation method according to claim 8, wherein the dose of the organometallic gas which is tetrakis(ethylmethylamino)hafnium or tetrakis(ethylmethylamino)zirconium is adjusted to 1.0×10⁻² Torr·s or higher or 1.0×10⁵ Langmuir units or higher, at the surface of the substrate to be treated.

15. An oxide thin film formation method according to claim 9, wherein the dose of the organometallic gas which is tetrakis(ethylmethylamino)hafnium or tetrakis(ethylmethylamino)zirconium is adjusted to 1.0×10⁻² Torr·s or higher or 1.0×10⁵ Langmuir units or higher, at the surface of the substrate to be treated.

16. An oxide thin film formation method according to claim 1, wherein the dose of the plasma gas is adjusted to 0.15 Torr·s or higher or 1.5×10⁵ Langmuir units or higher, at the surface of the substrate to be treated.

17. An apparatus for forming an oxide thin film, the apparatus comprising:
a reaction container having a mechanism for sustaining a substrate;
a temperature-controlling mechanism which can maintain the substrate at a temperature of higher than 0° C. and 150° C. or lower;
a source-feeding apparatus for feeding tetrakis(ethylmethylamino)hafnium or tetrakis(ethylmethylamino)zirconium;
a plasma gas generating apparatus adapted to feed water vapor-containing oxygen into a glass tube, and to apply high-frequency magnetic field to the glass tube, to thereby generate plasma inside the glass tube, thereby providing a plasma gas;
a first determination mechanism for determining the dose of tetrakis(ethylmethylamino)hafnium during feeding thereof in the reaction container; and
a second determination mechanism for determining the dose of the plasma gas in the reaction container.
